(19) United States
(12) Patent Application Publication
(10) Pub. No.: US 2019/0141840 A1
(43) Pub. Date: May 9, 2019

(54) SINGLE LAMINATION BLIND AND METHOD FOR FORMING THE SAME

(71) Applicant: R&D Circuits, Inc., South Plainfield, NJ (US)

(72) Inventors: Donald Eric Thompson, Fremont, CA (US); Dhananjaya Turpuseema, Whitehouse Station, NJ (US)

(21) Appl. No.: 16/051,772

(22) Filed: Aug. 1, 2018

Related U.S. Application Data
(60) Provisional application No. 62/541,307, filed on Aug. 4, 2017.

(51) Int. Cl. H05K 3/42; H05K 3/46; H05K 1/11

(52) U.S. Cl. CPC H05K 3/429; H05K 3/4608; H05K 3/4611; H05K 3/0047; H05K 3/422; H05K 3/423; H05K 1/115; H05K 3/427

(57) ABSTRACT

A method and structure that forms a PCB while removing or eliminating a stub from a via without back-drilling or doing multi-laminations. In the preferred embodiment, the printed circuit board includes a via extending through a plurality of stacked layers. The via includes a plated through hole that is connected to at least two other metalized layers. There is a portion of the via that is extraneous and that has a negative performance on the functionality of the printed circuit board. The single lamination buried via method adds a seed layer resist that prevents an electrical connection during electroplating thus preventing the via from metalizing where it is not desired.

### RELATED APPLICATION

The present non-provisional application claims priority to Provisional Application U.S. Ser. No. 62/541,307 filed on Aug. 4, 2017 by R&D Circuits, Inc. and claims priority thereunder pursuant to 35 U.S.C. 120.

### BACKGROUND OF THE INVENTION

### 1. Field of the Invention

The present invention relates to a structure and a method of removing a stub from a via without the need for back-drilling or to performing multi laminations. In particular, the present invention relates to a single lamination buried via method that adds a seed layer resist to prevent an electrical connection during electroplating which prevents the via from metalizing an undesired condition.

### 2. The Related Art

Printed Circuit Boards (PCBs) typically contain a plurality of vias, each of which electrically connects to a conductive trace on one layer of the PCB with one or more of the other layers of the PCB. Thus, illustratively, where a via interconnects two internal layers of the PCB, the portion of the via extending from an outermost one of the internal layers to the surface of the PCB are referred as a via stub. Via stubs do not provide any useful function in the circuit of the PCB and may result in signal distortion and/or other problems.

It would be advantageous to have a structure and a method for the removal or elimination of a stub from a via for a PCB that avoids the need for back-drilling or for performing multi-layered laminations thereby reducing lamination costs and reducing signal distortion and other problems associated with a vi stub.

### SUMMARY OF THE INVENTION

The present invention provides for a method of removing the stub from one via. This avoids using back-drilling or performing multi-laminates by a method of a single lamination buried via methodology employing a seed layer resisted to prevent an electrical connection during electro-plating thus preventing the via from metalizing where it is not desirable. In the present invention, the PCB includes a via extending through a plurality of stacked layers. The via includes a plated through hole that is connected to at least two other metalized layers. There is a portion of the via that is extraneous and that has a negative performance on the functionality of the PCB.

### BRIEF DESCRIPTION OF DRAWINGS

FIG. 1 illustrates a common construction of a PCB before the individual layers have been pressed together in accordance with the teachings of the present invention.

FIG. 2 illustrates the component of the FIG. 1 following their lamination to form the PCB.

FIG. 3 illustrates the drilling process for the vias of FIG. 1.

FIG. 4 shows deposition of a conductive layer used for electro-plating also referred to as a seed layer for FIG. 1

FIG. 5 shows the PCB of the electroplating of FIG. 1. In FIG. 5, the conductive material in the via (9) is formed by an electro-plating process. The seed-resist gap in the seed-resist layer can be selectively preventing plating by breaking the electrical conduction path which is required for electro-plating.

FIG. 6 illustrates the final board stage after the top and bottom layer are meshed and etched as part of a typical PCB fabrication process of FIG. 5. In FIG. 6, the top and bottom layers are masked and etched as part of a typical PCB fabrication process.

FIG. 7 shows the methodology of the present invention in which the seed-resist material is employed to separate the top and bottom electrical paths thus permitting two electrical transmission lines to share the via while remaining isolated from each other.

FIG. 8 is a flowchart showing a standard example of a via plating process for a PCB as described in FIGS. 1-6; and

FIG. 9 is a flow chart showing the single lamination methodology as described in FIG. 8 and in accordance with the teachings of the present invention.

### DETAILED DESCRIPTION OF PREFERRED EMBODIMENTS

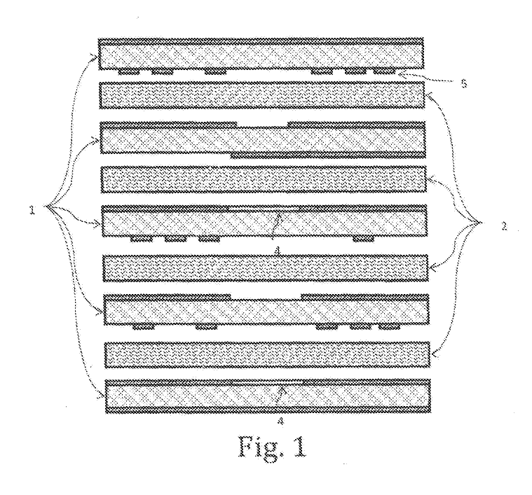

Referring now to FIGS. 1-9 of the drawings, FIG. 1 illustrates a common construction of a PCB before the individual layers are pressed together. A typical PCB is formed of multiple layers copper, copper clad core (1) and a partially cured dielectric also known as pre-preg (2). A seed-resist material (4) is deposited on two layers. FIG. 1 shows a common construction of a PCB before the individual layers have been pressed together. A typical PCB is made up of multiple layers of copper, copper clad core (1), and partially cured dielectric also known as pre-preg (2). Deposited on two layers is the seed-resist (4).

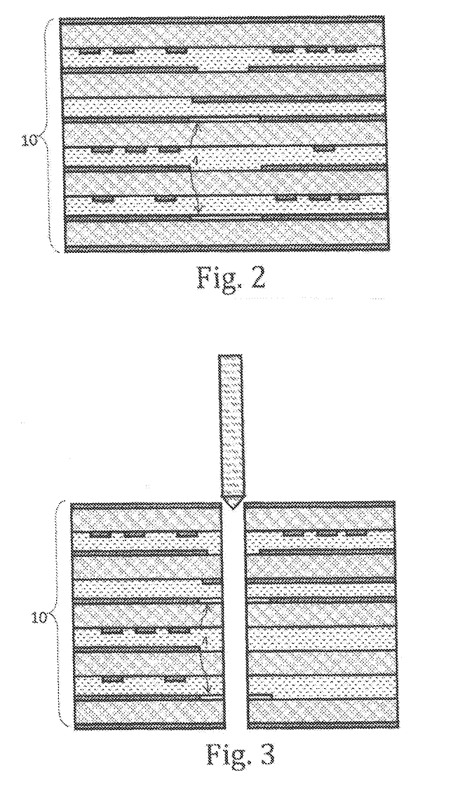

FIG. 2 shows the components in FIG. 1 after they have been laminated to form the PCB (10) or printed circuit board (10). FIG. 2 shows the components in FIG. 1 after they have been laminated. This forms the PCB (10) or circuit board.

FIG. 3 illustrates the drilling process for vias (9) formed in the PCB (10).

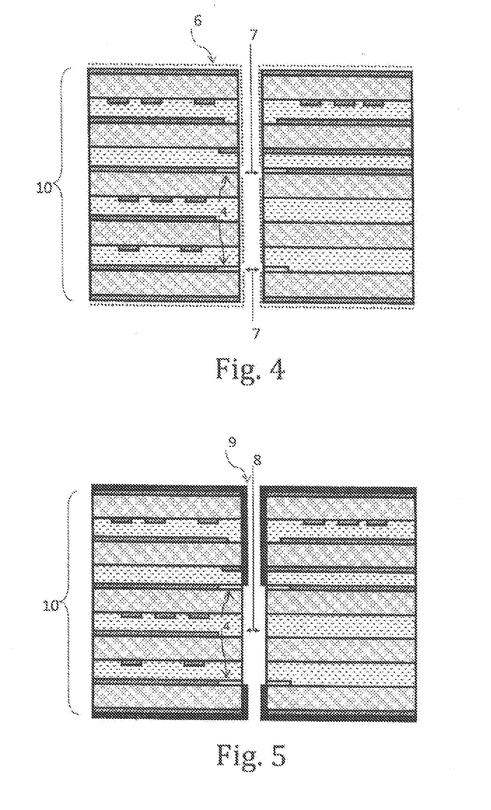

FIG. 4 shows deposition of a conductive layer used for electro-plating also referred to as a seed layer for FIG. 1. FIG. 4 shows the deposition of a conductive layer used for electroplating (6). This is sometimes referred to as the seed layer. Examples of this are electroless CU, Pd colloidal system, carbon colloidal system, or conductive polymer system. The deposited seed-resist material (4) will not allow the conductive seed layer to bond to the surface creating a gap in the seed layer at that location (7). Examples of this type of material are Teflon® or Kapton®.

FIG. 5 shows the PCB of the electroplating of FIG. 1. FIG. 5 shows the same board after electroplating. The conductive material in the via is formed by an electroplating process. The seed-resist gap in the seed layer can selectively prevent plating by breaking the electrical conduction path that is required for electroplating.

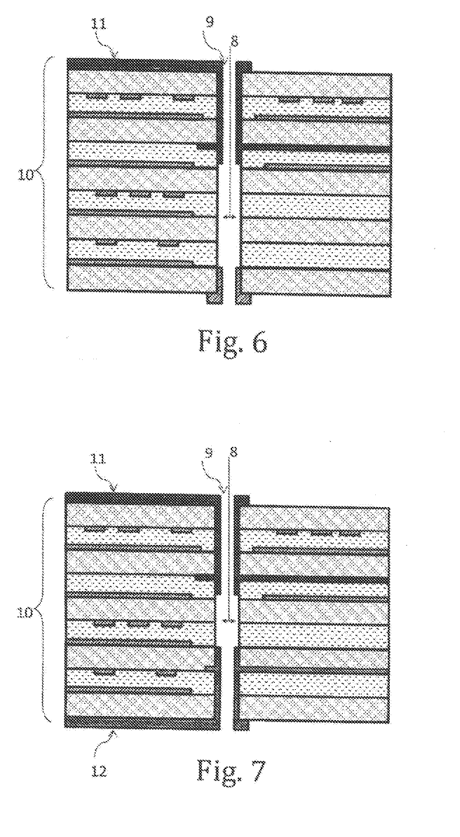

FIG. 6 illustrates the final board stage after the top and bottom layer are meshed and etched as part of a typical PCB fabrication process of FIG. 5. FIG. 6 shows the final board stage after the top and bottom layer are masked and etched as part of a typical PCB fabrication process.

FIG. 7 shows the methodology of the present invention in which the seed-resist material is employed to separate the top and bottom electrical paths thus permitting two electrical transmission lines to share the via while remaining isolated from each other. FIG. 7 shows the methodology and structure of the present invention. In this embodiment, the seed-resist material is used to separate the top and bottom electrical paths. This allows for two electrical transmission lines to share the via without while remaining electrically isolated from each other.

FIG. 8 is a flowchart showing a standard example of a via plating process for a PCB. FIG. 8 illustrates a standard example of constructing a via plating process for a PCB.

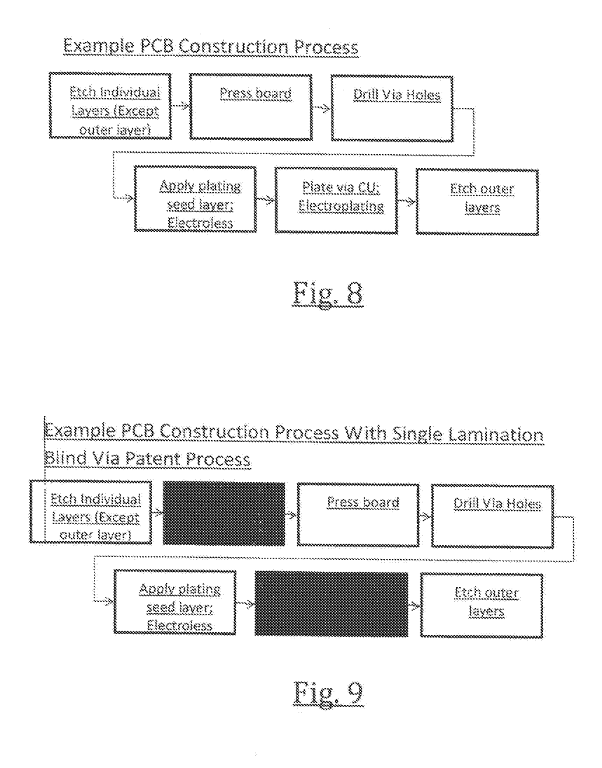

FIG. 9 is a flow chart showing the single lamination methodology in accordance with the teachings of the present invention. FIG. 9 describes the methodology of the present invention. In FIG. 8, the present invention discloses a method of forming a printed circuit board (PCB) while removing or preventing a stub from forming a via of a printed circuit board (PCB).

First a multi-layered printed circuit board (PCB) of individual layers is formed that are pressed together by first etching each of said individual layers of said PCB except for an outer layer.

Next a first signal trace is placed on any one of said layers of said PCB.

Then a second signal trace is placed on another layer of said PCB adding or inserting seed resist material to said layers of said PCB.

At least one via hole is drilled through said PCB and intersecting said first signal trace and said second signal trace with a conductive material that is electro-deposited on said layers of said first and said signal traces. Plated seed resist layer is then applied by electroless plating.

The outer layers are etched thereby preventing electrically conductive material from attaching to walls of said vias prior to electro-deposition of conductive material thereby electro-plating said via and adding or inserting seed-resist material on a wall of said via.

A seed-resist material is added or inserted into the PCB on said via hole to prevent electrically conductive material from attaching to a wall of said vias prior to electro-deposition of conductive material.

Embodiments described herein may include PCBs in various stages of manufacture, and related methods of fabrication of PCBs. For example, the description describes a single lamination PCB board manufacturing process, but the embodiment of this method extends to multi-lamination PCBs or other alternate construction methodologies.

In the foregoing description, numerous details are set forth to provide an understanding of the present invention.

The FIGS. depict the embodiments, implementations, and the configurations of the invention, and not the invention itself.

While the invention is susceptible to various modifications and alternative forms, specific embodiments thereof have been shown by way of example in the drawings and are herein described in detail. It should be understood, however, that it is not intended to limit the invention to the particular form disclosed, but rather, the invention is to cover all modifications, equivalents, and alternatives falling with the scope and spirit of the invention.

1. A method of forming a printed circuit board (PCB) while removing or preventing a stub from forming a via of a printed circuit board (PCS) the steps comprising:
forming a multi-layered printed circuit board (PCB) of individual layers that are pressed together by first etching each of said individual layers of said PCB except for the an outer layer;
placing a first signal trace on any one of said layers of said PCB;
placing a second signal trace on another layer of said PCB;
adding or inserting seed resist material to said layers of said PCB;
drilling at least one via hole through said PCB and intersecting said first signal trace and said second signal trace with a conductive material that is electro-deposited on said layers of said first and said signal traces;
applying plating seed resist layer by electroless plating; and etching outer layers thereby preventing electrically conductive material from attaching to the walls of said vias prior to electro-deposition of conductive material thereby electro-plating said via and adding or inserting seed-resist material on a wall of said via;
adding or inserting a seed-resist material into said PCB on said via hole to prevent electrically conductive material from attaching to a wall of said vias prior to electro-deposition of conductive material.

2. The method according to claim 1 when said multiple layers of said PCB include copper, copper clad core and partially cured dielectric (pre-preg).

3. The method according to claim 1 where said seed-resist material separates at the top and bottom electrical transmission lines showing said via while removing electrically isolation from each via.

4. A structure for a multi-layered a printed circuit board (PCB) comprising:
a multi-layered printed circuit board (PCB) formed of individual layers that pressed together that are first etching each of said individual layers of said PCB except for an outer layer;
a first signal trace placed on any one of said layers of said PCB;
a second signal trace placed on another layer of said PCB;
adding or inserting seed resist material to said layers of said PCB;
At least one via hole drilled through said PCB and intersecting said first signal trace and said second signal trace with a conductive material that is electro-deposited on said layers of said first and said signal traces;
plated seed resist layer applied by electroless plating to said layers; and said outer layers being etched thereby preventing electrically conductive material from attaching to walls of said vias prior to electro-deposition of conductive material thereby electro-plating said via and adding or inserting seed-resist material on a wall of said via;
seed-resist material added or inserted into said PCB on said via hole to prevent electrically conductive material from attaching to a wall of said vias prior to electro-deposition of conductive material.
